(19) United States
(12) Patent Application Publication
(10) Pub. No.: US 2023/0358835 A1
(43) Pub. Date: Nov. 9, 2023

(54) VARIATIONAL AUTOENCODER-BASED MAGNETIC RESONANCE WEIGHTED IMAGE SYNTHESIS METHOD AND DEVICE

(71) Applicant: ZHEJIANG LAB, Hangzhou (CN)

(72) Inventors: Jingsong LI, Hangzhou (CN); Ziyang CHEN, Hangzhou (CN); Wenyuan QIU, Hangzhou (CN); Qiqi TONG, Hangzhou (CN); Tianshu ZHOU, Hangzhou (CN)

(21) Appl. No.: 18/219,678

(22) Filed: Jul. 9, 2023

Related U.S. Application Data
(63) Continuation of application No. PCT/CN2023/080571, filed on Mar. 9, 2022.

(30) Foreign Application Priority Data
Nov. 4, 2022 (CN) 202211375033.5

(51) Int. Cl. G01R 33/56; G06N 3/0455; G06N 3/0464

(52) U.S. Cl. CPC G01R 33/5608; G06N 3/0455; G06N 3/0464

(57) ABSTRACT

The application discloses a variational autoencoder-based magnetic resonance weighted image synthesis method and device. The method includes the following steps: step S1: acquiring a multi-contrast real magnetic resonance weighted image and a magnetic resonance quantitative parametric image by using a magnetic resonance scanner; step S2: composing a magnetic resonance weighted image; step S3: constructing a pre-trained variational autoencoder model with an encoder-and-decoder structure; step S4: obtaining a variational autoencoder model; and step S5: synthesizing the magnetic resonance weighted image and the magnetic resonance quantitative parametric image into a second magnetic resonance weighted image by the variational auto-encoder model. In the application, the variational auto-encoder model is configured to obtain a proximate contrast information continuous distribution by training of the multi-contrast magnetic resonance weighted image, such that the variational autoencoder model involved in the application can be reconstructed to obtain magnetic resonance weighted images that are not present in training data.

### CROSS REFERENCE TO RELATED APPLICATIONS

This application claims the benefits of priority to Chinese Patent Application No. 202211375033.5 filed with the Chinese National Intellectual Property Office on Nov. 4, 2022 and entitled “Variational Autoencoder-based Magnetic Resonance Weighted Image Synthesis Method and Device”, the entire contents of which are incorporated herein by reference.

### TECHNICAL FIELD

The present application relates to the technical field of medical image processing, in particular to a variational autoencoder-based magnetic resonance weighted image synthesis method and device.

### BACKGROUND

Magnetic Resonance Imaging (MRI) is a non-invasive and ionizing radiation-free medical imaging method, which is widely used in scientific research and clinical practice.

Magnetic resonance imaging relies on the polarization of protons under a high-intensity magnetic field, and protons gradually return to an equilibrium state after being excited to be in a resonant state using radio frequency pulses. The above process is known as the relaxation process of protons. Magnetic resonance signals are electromagnetic signals generated in the relaxation process. According to the differences in parameters of an acquisition sequence, the magnetic resonance signals exhibit a weighted sum of different contrasts, including longitudinal relaxation parameter T₁ contrast weighting, transverse relaxation parameter T₂ contrast weighting, proton density PD contrast weighting, etc. Therefore, magnetic resonance imaging may obtain different contrast-weighted images by varying the parameters of the acquisition sequence, and the above different contrast-weighted images may reflect different tissue properties. Therefore, in an actual clinical examination process, a variety of magnetic resonance weighted images with different contrasts are often acquired, which results in the consumption of a lot of time for magnetic resonance examination and a heavy medical resource stress.

A quantitative magnetic resonance imaging method, which has evolved rapidly in recent years, offers a new idea to solve the above problems. The quantitative magnetic resonance imaging method acquires magnetic resonance quantitative parametric images of tissues, and the acquired magnetic resonance quantitative parametric images can be used to describe quantitative properties of the tissues. Corresponding magnetic resonance signals can be synthesized with the magnetic resonance quantitative parameters by setting appropriate acquisition parameters according to a magnetic resonance signal formula. In principle, a magnetic resonance weighted image with any contrast can be obtained. However, a magnetic resonance weighted image obtained by the synthesis method based on the magnetic resonance signal equation has certain limitations compared to actually acquired magnetic resonance weighted image due to errors in the measurement of magnetic resonance quantitative tissue parameters. In addition, studies have shown that T2FLAIR images synthesized via magnetic resonance quantitative parametric images cannot achieve the complete cerebrospinal fluid suppression effect.

The problem present in the synthesis process using the above formula is expected to be solved with deep learning methods. Recent studies use generative adversarial networks to achieve the synthesis of magnetic resonance weighted images. A better synthesis result can be achieved by taking the acquired magnetic resonance quantitative parametric images as the input of a generator, and taking the actually acquired magnetic resonance weighted images as labels for the training process of the generator, in cooperation with a discriminator performing adversarial training. However, the above method also has certain limitations, the deep learning method can only be used to synthesize magnetic resonance weighted images with contrasts existing in the training data due to limitations to the contrasts of the actually acquired magnetic resonance weighted images in the training data, which greatly limits the range of application of the magnetic resonance quantitative parametric images in synthesis of magnetic resonance weighted images with different contrasts.

To this end, a variational autoencoder-based magnetic resonance weighted image synthesis method and device are provided to solve the above technical problems.

### SUMMARY

The present application provides a variational autoencoder-based magnetic resonance weighted image synthesis method and device in order to solve the above technical problems.

The technical solutions adopted in the present application are as follows.

A variational autoencoder-based magnetic resonance weighted image synthesis method includes the following steps:
step S1: acquiring a multi-contrast real magnetic resonance weighted image and a magnetic resonance quantitative parametric image by using a magnetic resonance scanner;
step S2: synthesizing a first magnetic resonance weighted image according to a corresponding quantitative value in the magnetic resonance quantitative parametric image, assumed repetition time at the time of image signal synthesis, assumed echo time at the time of image signal synthesis and/or assumed inversion time at the time of image signal synthesis, composing the first magnetic resonance weighted image and the real magnetic resonance weighted image into a magnetic resonance weighted image;
step S3: constructing a pre-trained variational autoencoder model with an encoder-and-decoder structure;
step S4: constructing a training set by using the magnetic resonance weighted image and the magnetic resonance quantitative parametric image, training the pre-trained variational autoencoder model, and updating parameters of the pre-trained variational autoencoder model, to obtain a variational autoencoder model; and
step S5: synthesizing the magnetic resonance weighted image and the magnetic resonance quantitative parametric image into a second magnetic resonance weighted image by the variational autoencoder model.

Further, the real magnetic resonance weighted image and the magnetic resonance quantitative parametric image in the step S1 are generated by performing a preset scanning sequence via the magnetic resonance scanner.

Further, the magnetic resonance quantitative parametric image is composed of a T₁ quantitative image, a T₂ quantitative image and a proton density quantitative image.

Further, the real magnetic resonance weighted image includes at least any one of the following: a T₁-weighted conventional image, a T₂-weighted conventional image, a proton density-weighted image, a T₁-weighted Flair image and/or a T₂-weighted Flair image.

Further, step S3 specifically includes the following sub-steps:
step S31: constructing an encoder by using a plurality of three-dimensional convolutional layers each of which is followed by an encoding activation layer and a pooling layer;
step S32: constructing a decoder by using an encoding layer composed of a plurality of transposed convolutional layers and a decoding layer composed of a plurality of convolutional layers each of which is followed by a decoding activation layer; and
step S33: connecting the encoder and the decoder by using a fully connected layer, to obtain the pre-trained variational autoencoder model.

Further, step S4 specifically includes the following sub-steps:
step S41: registering the real magnetic resonance weighted image to the first magnetic resonance weighted image by using a linear registration method and a non-linear registration method, to obtain a registered real magnetic resonance image;
step S42: unifying resolutions of the registered real magnetic resonance image, the first magnetic resonance weighted image and the magnetic resonance quantitative parametric image by linear interpolation, to obtain a training set;
step S43: inputting the registered real magnetic resonance image and/or the first magnetic resonance weighted image into an encoder in the pre-trained variational autoencoder model, outputting a mean value and a variance in hypothetical multivariate normal distribution after convolution, and performing sampling operation on the mean value and the variance, to obtain a hidden layer variable characterizing contrast encoding;
step S44: connecting the encoder with an encoding layer of a decoder in the pre-trained variational autoencoder model by the fully connected layer;
step S45: making the hidden layer variable pass through the transposed convolutional layers in the encoding layer, and restoring the hidden layer variable to a contrast encoding knowledge matrix having the same size as the magnetic resonance quantitative parametric image;
step S46: combining the contrast encoding knowledge matrix with the magnetic resonance quantitative parametric image in the training set to obtain a matrix;
step S47: outputting the matrix by the decoding layer of the decoder to obtain a second magnetic resonance weighted image with a corresponding contrast, and calculating a loss function according to the real magnetic resonance weighted image with the corresponding contrast in the training set; and
step S48: repeating the steps S41-S47, setting a preset degree of learning, performing reverse gradient propagation according to the loss function, and updating parameters of the pre-trained variational autoencoder model until the loss function no longer descends to complete training, thereby obtaining the variational autoencoder model.

Further, the method of combining in the step S46 includes: splicing the contrast encoding knowledge matrix with the magnetic resonance quantitative parametric image in the training set, or splicing the contrast encoding knowledge matrix with the magnetic resonance quantitative parametric image in the training set after passing through the plurality of three-dimensional convolutional layers, or adding the contrast encoding knowledge matrix with the magnetic resonance quantitative parametric image in the training set.

Further, the real magnetic resonance weighted image with the corresponding contrast in the training set used to calculate the loss function in the step S47 has the same contrast as the input of the real magnetic resonance image and/or the first magnetic resonance weighted image in the step S43, and has the same individual as the magnetic resonance quantitative parametric image in the training set in the step S46.

Further, the training loss function of the pre-trained variational autoencoder model in the step S4 is:

$$Loss = \frac{1}{n} {\sum }_{i = 0}^{n} {\sum }_{j = 0}^{d} ( {σ}_{i , j}^{2} + {μ}_{i , j}^{2} - log {σ}_{i , j}^{2} ) + \frac{1}{n} {\sum }_{i = 0}^{n} {‖ {x}_{i} - {μ}_{i}^{′} ‖}^{2}$$

wherein σ and μ are the mean value and the variance in normal distribution of the hidden layer variable output by the encoder, μ′ is an output result of the decoder, xᵢ is the second magnetic resonance weighted image with the corresponding contrast, i is an input sample, j is an input sample used to extract contrast encoding information, and n and d are the corresponding amount of samples input when the loss function is calculated once.

The present application further provides a variational autoencoder-based magnetic resonance weighted image synthesis device, including a memory and one or more processors, wherein the memory stores executable codes therein, and the one or more processors, when executing the executable codes, are configured to implement the variational autoencoder-based magnetic resonance weighted image synthesis method in any one of the above embodiments.

The present application further provides a computer-readable storage medium storing a program thereon, wherein the program, when executed by a processor, implements the variational autoencoder-based magnetic resonance weighted image synthesis method in any one of the above embodiments.

The present application has the following beneficial effects:
1. The magnetic resonance weighted image synthesis method based on the magnetic resonance signal formula of the present application can synthesize corresponding magnetic resonance signals by setting appropriate acquisition parameters and utilizing magnetic resonance quantitative parameters. However, a magnetic resonance weighted image obtained by the synthesis method based on the magnetic resonance signal equation has certain limitations compared to actually acquired magnetic resonance weighted image due to errors in the measurement of magnetic resonance quantitative tissue parameters. According to the present application, the deep learning method for synthesizing a magnetic resonance weighted image can learn features of the actually acquired magnetic resonance weighted image using a deep learning model, thereby obtaining the synthesized magnetic resonance weighted image that is more consistent with the actually acquired magnetic resonance weighted image.
2. Current synthesis methods based on other deep learning methods are limited to the contrast of the actually acquired magnetic resonance weighted images in the training data and thus can only synthesize a magnetic resonance weighted image with existing contrast in the training data, which greatly limits the range of application of the magnetic resonance quantitative parametric images in the synthesis of the magnetic resonance weighted images with different contrasts. According to the present application, the variational autoencoder model is used and can obtain the proximate contrast information continuous distribution of by training of magnetic resonance weighted images having multiple contrasts, such that the variational autoencoder model involved in the present application can be reconstructed to obtain magnetic resonance weighted images that are not present in the training data.
3. According to the present application, the magnetic resonance weighted images input by the encoder are decoupled from the real magnetic resonance weighted images serving as training labels of the decoder at the individual level in the training of the conditional variational autoencoder model, such that the encoder of the variational autoencoder model learns contrast information that is independent of the individual. The decoupling in the above training process may extract low-dimensional contrast encoding information using magnetic resonance weighted images of any individual such that a large number of synthesized magnetic resonance weighted images with target contrast can be generated using magnetic resonance weighted images of a single individual in a practical application process.
4. The variational autoencoder is a type of common data generation models, and the encoder of the variational autoencoder can image input high-dimensional data to a simple multivariate normal distribution. The corresponding hidden layer variable can be obtained by sampling in this distribution, and can reflect certain type of low-dimensional features of the input high-dimensional data, and the values of the hidden layer variable conform to the above normal distribution. Based on the above features of the variational autoencoder, the contrast information of the corresponding magnetic resonance weighted images can be mapped to one multivariate normal distribution by utilizing the decoder of the variational autoencoder, and the corresponding hidden layer variable can be obtained by sampling in this distribution, which reflect the contrast information of the high-dimensional magnetic resonance weighted image. According to this contrast information, the decoder of the variational autoencoder is used to achieve synthesis and reconstruction of the magnetic resonance weighted images with the corresponding contrast according this contrast information in conjunction with the magnetic resonance quantitative parametric image of the individual. Since magnetic resonance weighted images with the same contrast of different individuals are consistent in low-dimensional contrast information, the magnetic resonance weighted images of different individuals can be used as input of the variational autoencoder, and then the corresponding contrast information can be sampled. By training of the magnetic resonance weighted images with multiple contrasts, a proximate contrast information continuous distribution can be obtained, such that the variational autoencoder model can be reconstructed to obtain the magnetic resonance weighted images that are not present in the training data. According to the present application, the conditional variational autoencoder model is employed, and the magnetic resonance quantitative image of an individual is taken as a condition of the variational autoencoder, thereby controlling the variational autoencoder to accurately generate the synthesized magnetic resonance weighted image of this individual.

### BRIEF DESCRIPTION OF FIGURES

FIG. 1 is a flowchart of a variational autoencoder-based magnetic resonance weighted image synthesis method according to the present application;

FIG. 2 is a structural diagram of a model for a conditional variational autoencoder used in an embodiment; and

FIG. 3 is a schematic structural diagram of a variational autoencoder-based magnetic resonance weighted image synthesis device according to the present application.

### DETAILED DESCRIPTION

The following description of at least one exemplary embodiment is merely illustrative in practice and in no way serves as any limitation on the present application and its application or uses. Based on the embodiments of the present application, other embodiments obtained by those of ordinary skill in the art without creative work all fall within the scope of protection of the present application.

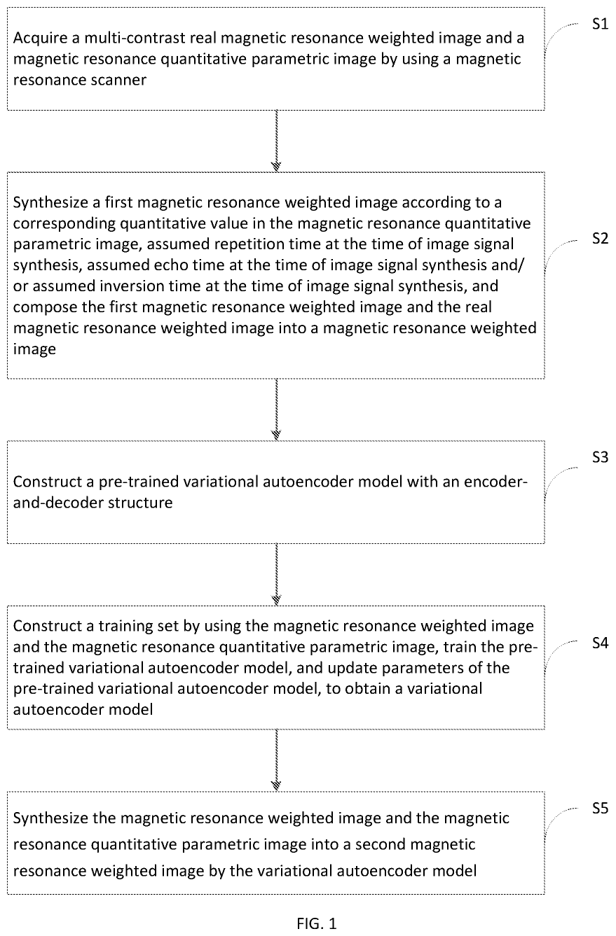

Referring to FIG. 1, a variational autoencoder-based magnetic resonance weighted image synthesis method includes the following steps:
step S1: a multi-contrast real magnetic resonance weighted image and a magnetic resonance quantitative parametric image are acquired by using a magnetic resonance scanner.

The real magnetic resonance weighted image and the magnetic resonance quantitative parametric image are generated by performing a preset scanning sequence via the magnetic resonance scanner. The magnetic resonance quantitative parametric image is composed of a T₁ quantitative image, a T₂ quantitative image and a proton density quantitative image.

The real magnetic resonance weighted image includes at least any one of a T₁-weighted conventional image, a T₂-weighted conventional image, a proton density-weighted image, a T₁-weighted Flair image, and/or a T₂-weighted Flair image.
Step S2: a first magnetic resonance weighted image is synthesized according to a corresponding quantitative value in the magnetic resonance quantitative parametric image, assumed repetition time at the time of image signal synthesis, assumed echo time at the time of image signal synthesis and/or assumed inversion time at the time of image signal synthesis, the first magnetic resonance weighted image and the real magnetic resonance weighted image are composed into a magnetic resonance weighted image.
Step S3: a pre-trained variational autoencoder model with an encoder-and-decoder structure is constructed.
Step S31: an encoder is constructed by using a plurality of three-dimensional convolutional layers each of which is followed by an encoding activation layer and a pooling layer.
Step S32: a decoder is constructed by using an encoding layer composed of a plurality of transposed convolutional layers and a decoding layer composed of a plurality of convolutional layers each of which is followed by a decoding activation layer.
Step S33: the encoder and the decoder are connected by using a fully connected layer, to obtain the pre-trained variational autoencoder model.
Step S4: a training set is constructed by using the magnetic resonance weighted image and the magnetic resonance quantitative parametric image, the pre-trained variational autoencoder model is trained, and parameters of the pre-trained variational autoencoder model are updated, to obtain a variational autoencoder model.
Step S41: the real magnetic resonance weighted image is registered to the first magnetic resonance weighted image by using a linear registration method and a non-linear registration method, to obtain a registered real magnetic resonance image.
Step S42: resolutions of the registered real magnetic resonance image, the first magnetic resonance weighted image and the magnetic resonance quantitative parametric image are unified by linear interpolation, to obtain a training set.
Step S43: the registered real magnetic resonance image and/or the first magnetic resonance weighted image are/is input into an encoder in the pre-trained variational autoencoder model, a mean value and a variance in hypothetical multivariate normal distribution are output after convolution, and sampling operation is performed on the mean value and the variance, to obtain a hidden layer variable characterizing contrast encoding.
Step S44: the encoder is connected with an encoding layer of a decoder in the pre-trained variational autoencoder model by the fully connected layer.
Step S45: the hidden layer variable passes through the transposed convolutional layers in the encoding layer, and the hidden layer variable is restored to a contrast encoding knowledge matrix having the same size as the magnetic resonance quantitative parametric image.
Step S46: the contrast encoding knowledge matrix is combined with the magnetic resonance quantitative parametric image in the training set to obtain a matrix.

The method of combining includes: splicing the contrast encoding knowledge matrix with the magnetic resonance quantitative parametric image in the training set, or splicing the contrast encoding knowledge matrix with the magnetic resonance quantitative parametric image in the training set after passing through the plurality of three-dimensional convolutional layers, or adding the contrast encoding knowledge matrix with the magnetic resonance quantitative parametric image in the training set.
Step S47: the matrix is output by the decoding layer of the decoder to obtain a second magnetic resonance weighted image with a corresponding contrast, and a loss function is calculated according to the real magnetic resonance weighted image with the corresponding contrast in the training set.

The real magnetic resonance weighted image with the corresponding contrast in the training set used to calculate the loss function in the step S47 has the same contrast as the input of the real magnetic resonance image and/or the first magnetic resonance weighted image in the step S43, and has the same individual as the magnetic resonance quantitative parametric image in the training set in the step S46.
Step S48: the steps S41-S47 are repeated, a preset degree of learning is set, reverse gradient propagation is performed according to the loss function, and parameters of the pre-trained variational autoencoder model are updated until the loss function no longer descends to complete training, thereby obtaining the variational autoencoder model.

The training loss function of the pre-trained variational autoencoder model is:

$$Loss = \frac{1}{n} {\sum }_{i = 0}^{n} {\sum }_{i = 0}^{d} ( {σ}_{i , j}^{2} + {μ}_{i , j}^{2} - log {σ}_{i , j}^{2} ) + \frac{1}{n} {\sum }_{i = 0}^{n} {‖ {x}_{i} - {μ}_{i}^{′} ‖}^{2}$$

wherein σ and μ are the mean value and the variance in normal distribution of the hidden layer variable output by the encoder, μ′ is an output result of the decoder, xᵢ is the second magnetic resonance weighted image with the corresponding contrast, i is an input sample, j is an input sample used to extract contrast encoding information, and n and d are the corresponding amount of samples input when the loss function is calculated once.
Step S5: the magnetic resonance weighted image and the magnetic resonance quantitative parametric image are synthesized into a second magnetic resonance weighted image by the variational autoencoder model.

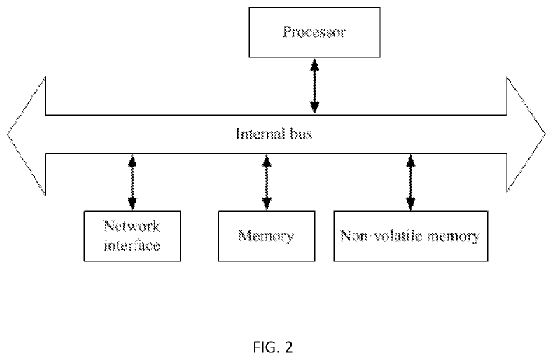

Referring to FIG. 2, Embodiment: a conditional variational autoencoder-based multi-contrast magnetic resonance weighted image synthesis method includes the following steps.
Step S1: a multi-contrast real magnetic resonance weighted image and a magnetic resonance quantitative parametric image are acquired by using a magnetic resonance scanner.

The real magnetic resonance weighted image and the magnetic resonance quantitative parametric image are generated by performing a preset scanning sequence via the magnetic resonance scanner.

The magnetic resonance quantitative parametric image is composed of a T₁ quantitative image, a T₂ quantitative image and a proton density quantitative image.

The real magnetic resonance weighted image includes at least any one of a T₁-weighted conventional image, a T₂-weighted conventional image, a proton density-weighted image, a T₁-weighted Flair image, and/or a T₂-weighted Flair image.

The magnetic resonance quantitative parametric image and the real magnetic resonance weighted image are acquired by performing specific scanning sequence via the magnetic resonance scanner. The magnetic resonance quantitative parametric image can be acquired by employing a plurality of scanning sequences, for example, when the T₁ quantitative image is acquired, an inversion recovery sequence at multiple inversion times, for example, an MP2RAGE sequence, may be employed, and a corresponding Tᵢ quantitative image may be calculated using the corresponding relation between signal values in the acquired real magnetic resonance weighted image and the acquisition parameter (inversion time). When the T₂ quantitative image is acquired, a spin echo sequence at multiple echo times may be employed, a corresponding T₂ quantitative image may be calculated using the corresponding relation between signal values and the acquisition parameter (echo time) in the acquired real magnetic resonance weighted image. A variety of magnetic resonance quantitative parametric images can also be obtained in single scanning by novel quantitative magnetic resonance imaging sequences, including an MDME (Multiple Dynamic Multiple Echo) sequence and an MRF (Magnetic Resonance Fingerprinting) sequence, and a plurality of magnetic resonance quantitative parametric images can be obtained simultaneously by a corresponding sequence-specific reconstruction method, which will not be described in detail. In this embodiment, the magnetic resonance quantitative parametric image is obtained by the magnetic resonance fingerprinting, MRF, sequence. For the method involved in the present application, the specific manner of acquiring the magnetic resonance quantitative parametric image does not affect all subsequent steps of the method involved in the present application, and therefore is only one specific example of the present application and does not limit the use of other methods in other embodiments to acquire the magnetic resonance quantitative parametric image. The real magnetic resonance weighted image may be obtained by employing a particular scanning sequence and scanning parameters, and when different scanning sequences are selected or different scanning parameters are set, the real magnetic resonance weighted images with different contrasts may be obtained. In this embodiment, the real magnetic resonance weighted images with different contrasts are obtained by controlling the repetition time, echo time and inversion time. The number of types of acquired real magnetic resonance weighted image contrasts is greater than 5 in order to guarantee subsequent training effects and to take into account the efficiency. The magnetic resonance quantitative parametric image and the real magnetic resonance weighted image acquired in this embodiment belong to the same individual and the number of individuals is greater than 10.
Step S2: a first magnetic resonance weighted image is synthesized according to a corresponding quantitative value in the magnetic resonance quantitative parametric image, assumed repetition time at the time of image signal synthesis, assumed echo time at the time of image signal synthesis and/or assumed inversion time at the time of image signal synthesis, and the first magnetic resonance weighted image and the real magnetic resonance weighted image are composed into a magnetic resonance weighted image.

When the images are the T₁-weighted conventional image, the T₂-weighted conventional image, and the proton density-weighted image, the first magnetic resonance weighted image is synthesized by formula I as follows:

$$S = PD * {e}^{- \frac{TE}{{T}_{2}}} * ( 1 - {e}^{- \frac{TR}{{T}_{1}}} )$$

wherein T₁, T₂ and PD are corresponding quantitative values in the T₁ quantitative image, the T₂ quantitative image and the proton density quantitative image, respectively; TR is the assumed repetition time at the time of image signal synthesis; and TE is the assumed echo time at the time of image signal synthesis. Appropriate TR and TE parameters are selected such that the contrast conforms to the T₁-weighted conventional image.

When the image is the T₁-weighted Flair image or the T₂-weighted Flair image or other images containing a single inversion pulse sequence, the first magnetic resonance weighted image is synthesized by formula II as follows:

$$S = PD * {e}^{- \frac{TE}{{T}_{2}}} * ( 1 - 2 * {e}^{- \frac{TR}{T 1}} + {e}^{- \frac{TR}{{T}_{1}}} )$$

wherein T₁, T₂ and PD are corresponding quantitative values in the T₁ quantitative image, the T₂ quantitative image and the proton density quantitative image, respectively; TR is the assumed repetition time at the time of image signal synthesis; TE is the assumed echo time at the time of image signal synthesis; and TI is the assumed inversion time at the time of image signal synthesis.
Step S3: a pre-trained variational autoencoder model with an encoder-and-decoder structure is constructed.
Step S31: an encoder is constructed by using a plurality of three-dimensional convolutional layers each of which is followed by an encoding activation layer and a pooling layer.

An activation function of the encoding activation layer is a “relu” function and a pooling function of the pooling layer is maximum pooling.
Step S32: a decoder is constructed by using an encoding layer composed of a plurality of transposed convolutional layers and a decoding layer composed of a plurality of convolutional layers each of which is followed by a decoding activation layer.

An activation function of the decoding activation layer is a “relu” function.
Step S33: the encoder and the decoder are connected by using a fully connected layer, to obtain the pre-trained variational autoencoder model.
Step S4: a training set is constructed by using the magnetic resonance weighted image and the magnetic resonance quantitative parametric image, the pre-trained variational autoencoder model is trained, and parameters of the pre-trained variational autoencoder model are updated, to obtain a variational autoencoder model.

Assuming that one piece of low-dimensional contrast information z is present in high-dimensional magnetic resonance weighted image, and that low-dimensional contrast information can be approximately expressed by a simple multivariate normal distribution, there is:

z˜ [symbol] (0,I)

wherein I represents an identity matrix, and thus z is a multi-dimensional random variable subjected to standard multivariate normal distribution.

Assuming that the encoder of the conditional variational autoencoder model conforms to posterior distribution p_{θe}(z|X) and the decoder conforms to posterior distribution p_{θd}(X|z, Y), X represents the high-dimensional magnetic resonance weighted image, Y represents the magnetic resonance quantitative parametric image, and θe and θd represent parameters of an encoder and a decoder of a hypothetical model. Based on a variational Bayesian algorithm, the used encoder of p_{θe}(z|X) fits the posterior distribution p_{θe}(z|X). p_{θe}(z|X) is the posterior distribution in an actual model.

log p_{θ}(X|Y) is maximized in model training, which expands by utilizing the full probability theorem to yield:

log p_{θ}(X|Y)=∫q_{θe}(z|X)log p_{θd}(X|z,Y)d_{z}.

The training loss function of the pre-trained variational autoencoder model is:

$$Loss = \frac{1}{n} {\sum }_{i = 0}^{n} {\sum }_{j = 0}^{d} ( {σ}_{i , j}^{2} + {μ}_{i , j}^{2} - log {σ}_{i , j}^{2} ) + \frac{1}{n} {\sum }_{i = 0}^{n} {‖ {x}_{i} - {μ}_{i}^{′} ‖}^{2}$$

wherein σ and μ are the mean value and the variance in normal distribution of the hidden layer variable output by the encoder, μ′ is an output result of the decoder, xᵢ is the second magnetic resonance weighted image with the corresponding contrast, i is an input sample, j is an input sample used to extract contrast encoding information, and n and d are the corresponding amount of samples input when the loss function is calculated once.
Step S41: the real magnetic resonance weighted image is registered to the first magnetic resonance weighted image by using a linear registration method and a non-linear registration method, to obtain a registered real magnetic resonance image.
Step S42: resolutions of the registered real magnetic resonance image, the first magnetic resonance weighted image and the magnetic resonance quantitative parametric image are unified by linear interpolation, to obtain a training set.
Step S43: the registered real magnetic resonance image and/or the first magnetic resonance weighted image are/is input into the encoder in the pre-trained variational autoencoder model, the mean value and the variance in hypothetical multivariate normal distribution are output after convolution, and sampling operation is performed on the mean value and the variance, to obtain the hidden layer variable z characterizing contrast encoding.

The sampling formula is as follows:

z=σ+λμ

wherein σ and μ are the mean value and variance in normal distribution of the hidden layer variable output by the encoder, and λ conforms to standard normal distribution.

The above training set is used as data for model training. In the model training process, the registered real magnetic resonance image and/or first magnetic resonance weighted image with a certain contrast of a certain individual are/is randomly selected to serve as input of the encoder.

When the first magnetic resonance weighted image is selected, the first magnetic resonance weighted image is synthesized from the pre-processed magnetic resonance quantitative parametric image. Specifically, when used for the input of the encoder in the training process, the contrast of the first magnetic resonance weighted image needs to consistent with the acquired real magnetic resonance weighted image, that is, the contrast of the first magnetic resonance weighted image needs to be consistent with a certain type of the contrast of the acquired real magnetic resonance weighted image contrast.
Step S44: the encoder is connected with the encoding layer of the decoder in the pre-trained variational autoencoder model by the fully connected layer.
Step S45: the hidden layer variable passes through the transposed convolutional layers in the encoding layer, and the hidden layer variable is restored to a contrast encoding knowledge matrix M having the same size as the magnetic resonance quantitative parametric image.
Step S46: the contrast encoding knowledge matrix M is combined with the magnetic resonance quantitative parametric image in the training set to obtain a matrix F.

The method of combining includes: splicing the contrast encoding knowledge matrix M with the magnetic resonance quantitative parametric images in the training set, or splicing the contrast encoding knowledge matrix M with the magnetic resonance quantitative parametric images in the training set after passing through the plurality of three-dimensional convolutional layers, or adding the contrast encoding knowledge matrix M with the magnetic resonance quantitative parametric images in the training set.

Specifically, concatenating the contrast encoding knowledge matrix M with the magnetic resonance quantitative parametric images includes the T₁ quantitative image, the T₂ quantitative image and the proton density quantitative image to obtain the matrix F.
Step S47: the matrix is output by the decoding layer of the decoder to obtain a second magnetic resonance weighted image with a corresponding contrast, and a loss function is calculated according to the real magnetic resonance weighted image with the corresponding contrast in the training set.
Step S48: steps S41-S47 are repeated, a preset degree of learning is set, reverse gradient propagation is performed according to the loss function, and parameters of the pre-trained variational autoencoder model are updated until the loss function no longer descends to complete training, thereby obtaining the variational autoencoder model.

The reverse propagation model is performed on the model based on the loss function, the parameters of the model are updated, an Adam optimizer is used during model training in the embodiment, and the corresponding learning rate is set to be 0.0001.
Step S5: the magnetic resonance weighted image and the magnetic resonance quantitative parametric image are synthesized into the second magnetic resonance weighted image by the variational autoencoder model.

The trained conditional variational autoencoder model is loaded, and the magnetic resonance weighted image and the magnetic resonance quantitative parametric image are selected as the input of the encoder. The pre-trained variational autoencoder model uses the real magnetic resonance weight image and the first magnetic resonance weight image as training data when in training, so that both the real magnetic resonance weight image and the first magnetic resonance weight image can be selected as the input of the encoder in this step. The individuals selected here are not correlated with the second magnetic resonance weighted image output by the final model, and therefore, a target magnetic resonance weighted image of any individual is selected. Due to the model training features, the target magnetic resonance weighted image selected here may have a contrast type that has not been present in the training data set. Therefore, different types of magnetic resonance weighted data are thus selected as input to extract the hidden layer variable according to the practical application demands, and an example employed here is that first magnetic resonance weighted image data having a contrast type that has not been present in the training data set is taken as the input of the model. First, first magnetic resonance weighted image data having a contrast type that has not been present in the training data set is constructed, the appropriate synthesis parameters are selected, and the magnetic resonance signal synthesis formula I or the magnetic resonance signal synthesis formula II is selected, thereby synthesizing the first magnetic resonance weighted image data. This synthesized data is input into the encoder of the loaded conditional variational autoencoder model to output the mean and the variance in posterior normal distribution of the hidden layer variable, and sampling is performed by the sampling formula to obtain the hidden layer variable z.

The second magnetic resonance weighted image with the corresponding contrast is synthesized by using the trained decoder based on the extracted hidden layer variable and the magnetic resonance quantitative parametric image.

The trained conditional variational autoencoder model is loaded. An extracted hidden layer variable and a magnetic resonance quantitative parametric image of a certain individual are selected. The individual selected here determines the conditional variational autoencoder to output a second magnetic resonance weighted image of the individual.

Corresponding to the embodiment of the foregoing conditional variational autoencoder-based multi-contrast magnetic resonance weighted image synthesis method, the present application also provides an embodiment of a conditional variational autoencoder-based multi-contrast magnetic resonance weighted image synthesis device.

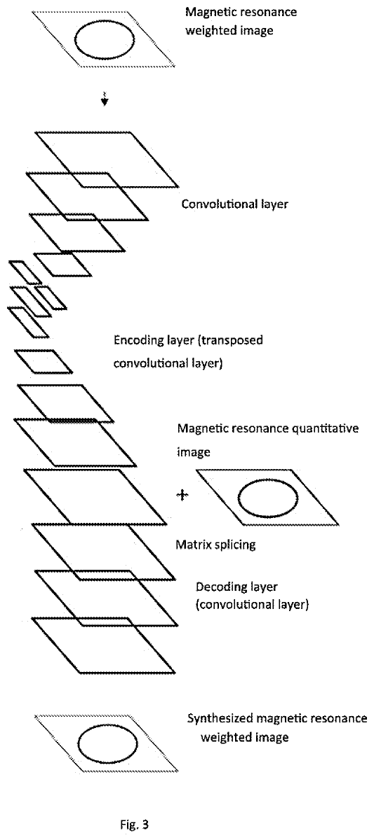

Referring to FIG. 3, an embodiment of the present application provides a conditional variational autoencoder-based multi-contrast magnetic resonance weighted image synthesis device, including a memory and one or more processors, wherein the memory stores executable codes therein, and the one or more processors, when executing the executable codes, are configured to implement the variational autoencoder-based magnetic resonance weighted image synthesis method in the above embodiment.

The embodiment of the conditional variational autoencoder-based multi-contrast magnetic resonance weighted image synthesis device of the present application can be applied to any device with data processing capability, which can be a device or apparatus such as a computer. The device embodiment may be implemented in software, or in hardware or a combination of hardware and software. In an example that implementation is achieved by software, as a device in a logical sense, it is formed by reading corresponding computer program instructions in a non-volatile memory into a memory by a processor of any device with data processing capability. From the hardware level, as shown in FIG. 3 which shows a hardware structural diagram of any device with data processing capability on which a conditional variational autoencoder-based multi-contrast magnetic resonance weighted image synthesis device is located according to the present application, in addition to a processor, a memory, a network interface, and a non-volatile memory shown in FIG. 3, any device with data processing capability, on which the device of the embodiment is located, may also include other hardware generally according to the actual function of the any device with data processing capability, which is not repeated here.

The implementation process of the functions and effects of the various units in the above device specifically refer to the implementation process of the corresponding steps in the above method, which is not repeated here.

Since the device embodiment substantially corresponds to the method embodiment, the relevant part can refer to the description of the method embodiment. The above described device embodiment is merely illustrative, wherein the units illustrated as separate components may be or may not be physically separated, and components shown as units may be or may not be physical units, i.e., may be located at one place, or may be distributed on a plurality of network units. Some or all of modules may be selected according to practical needs to achieve the objectives of the solutions of the present application. A person of ordinary skill in the art can understand and implement the embodiments without inventive step.

An embodiment of the present application also provide a computer-readable storage medium storing a program thereon, wherein the program, when executed by a processor, implements the variational autoencoder-based magnetic resonance weighted image synthesis method in the above embodiment.

The computer-readable storage medium may be an internal storage unit, such as a hard disk or a memory, of any device with data processing capability according to any of the foregoing embodiments. The computer-readable storage medium may also be an external storage device of any data device with data processing capability, such as a plug-in type hard disk, SmartMedia Card (SMC), SD card, Flash Card, or the like equipped on the device. Further, the computer-readable storage medium can also include both an internal storage unit and an external storage device of any device data processing capability. The computer-readable storage medium is configured to store the computer program and other programs and data required by any device with data processing capability, but may also be configured to temporarily store data that has been or will be output.

The above are merely preferred embodiments of the present application and are not intended to limit the present application, which may suffer from various modifications and variations for those skilled in the art. Any modification, equivalent replacement, improvement and the like in the spirit and principle of the present application are included in the scope of protection of the present application.

What is claimed is:

1. A variational autoencoder-based magnetic resonance weighted image synthesis method, comprising the following steps:
step S1: acquiring a multi-contrast real magnetic resonance weighted image and a magnetic resonance quantitative parametric image by using a magnetic resonance scanner;
step S2: synthesizing a first magnetic resonance weighted image according to a corresponding quantitative value in the magnetic resonance quantitative parametric image, assumed repetition time at the time of image signal synthesis, assumed echo time at the time of image signal synthesis and/or assumed inversion time at the time of image signal synthesis, and composing the first magnetic resonance weighted image and the real magnetic resonance weighted image into a magnetic resonance weighted image;
step S3: constructing a pre-trained variational autoencoder model with an encoder-and-decoder structure;
step S4: constructing a training set by using the magnetic resonance weighted image and the magnetic resonance quantitative parametric image, training the pre-trained variational autoencoder model, and updating parameters of the pre-trained variational autoencoder model, to obtain a variational autoencoder model; and
step S5: synthesizing the magnetic resonance weighted image and the magnetic resonance quantitative parametric image into a second magnetic resonance weighted image by the variational autoencoder model.

2. The variational autoencoder-based magnetic resonance weighted image synthesis method according to claim 1, wherein the real magnetic resonance weighted image and the magnetic resonance quantitative parametric image in the step S1 are generated by performing a preset scanning sequence via the magnetic resonance scanner.

3. The variational autoencoder-based magnetic resonance weighted image synthesis method according to claim 1, wherein the magnetic resonance quantitative parametric image is composed of a T₁ quantitative image, a T₂ quantitative image and a proton density quantitative image.

4. The variational autoencoder-based magnetic resonance weighted image synthesis method according to claim 1, wherein the real magnetic resonance weighted image comprises at least any one of a T₁-weighted conventional image, a T2-weighted conventional image, a proton density-weighted image, a T₁-weighted Flair image and/or a T₂-weighted Flair image.

5. The variational autoencoder-based magnetic resonance weighted image synthesis method according to claim 1, wherein the step S3 specifically comprises the following sub-steps:
step S31: constructing an encoder by using a plurality of three-dimensional convolutional layers each of the convolutional layer is followed by an encoding activation layer and a pooling layer;
step S32: constructing a decoder by using an encoding layer composed of a plurality of transposed convolutional layers and a decoding layer composed of a plurality of convolutional layers each of which is followed by a decoding activation layer; and
step S33: connecting the encoder and the decoder by using a fully connected layer, to obtain the pre-trained variational autoencoder model.

6. The variational autoencoder-based magnetic resonance weighted image synthesis method according to claim 1, wherein the step S4 specifically comprises the following sub-steps:
step S41: registering the real magnetic resonance weighted image to the first magnetic resonance weighted image by using a linear registration method and a non-linear registration method, to obtain a registered real magnetic resonance image;
step S42: unifying resolutions of the registered real magnetic resonance image, the first magnetic resonance weighted image and the magnetic resonance quantitative parametric image by linear interpolation, to obtain a training set;
step S43: inputting the registered real magnetic resonance image and/or the first magnetic resonance weighted image into an encoder in the pre-trained variational autoencoder model, outputting a mean value and a variance in hypothetical multivariate normal distribution after convolution, and performing sampling operation on the mean value and the variance, to obtain a hidden layer variable characterizing contrast encoding;
step S44: connecting the encoder with an encoding layer of a decoder in the pre-trained variational autoencoder model by the fully connected layer;
step S45: making the hidden layer variable pass through the transposed convolutional layers in the encoding layer, and restoring the hidden layer variable to a contrast encoding knowledge matrix having the same size as the magnetic resonance quantitative parametric image;
step S46: combining the contrast encoding knowledge matrix with the magnetic resonance quantitative parametric image in the training set to obtain a matrix;
step S47: outputting the matrix by the decoding layer of the decoder to obtain a second magnetic resonance weighted image with a corresponding contrast, and calculating a loss function according to the real magnetic resonance weighted image with the corresponding contrast in the training set; and
step S48: repeating the steps S41-S47, setting a preset degree of learning, performing reverse gradient propagation according to the loss function, and updating parameters of the pre-trained variational autoencoder model until the loss function no longer descends to complete training, thereby obtaining the variational autoencoder model.

7. The variational autoencoder-based magnetic resonance weighted image synthesis method according to claim 6, wherein the method of combining in the step S46 comprises: splicing the contrast encoding knowledge matrix with the magnetic resonance quantitative parametric image in the training set, or splicing the contrast encoding knowledge matrix with the magnetic resonance quantitative parametric image in the training set after passing through the plurality of three-dimensional convolutional layers, or adding the contrast encoding knowledge matrix with the magnetic resonance quantitative parametric image in the training set.

8. The variational autoencoder-based magnetic resonance weighted image synthesis method according to claim 6, wherein the real magnetic resonance weighted image with the corresponding contrast in the training set used to calculate the loss function in the step S47 has the same contrast as the input of the real magnetic resonance image and/or the first magnetic resonance weighted image in the step S43, and has the same individual as the magnetic resonance quantitative parametric image in the training set in the step S46.

9. The variational autoencoder-based magnetic resonance weighted image synthesis method according to claim 1, wherein the training loss function of the pre-trained variational autoencoder model in the step S4 is:
$$Loss = \frac{1}{n} {\sum }_{i = 0}^{n} {\sum }_{j = 0}^{d} ( {σ}_{i , j}^{2} + {μ}_{i , j}^{2} - log {σ}_{i , j}^{2} ) + \frac{1}{n} {\sum }_{i = 0}^{n} {‖ {x}_{i} - {μ}_{i}^{′} ‖}^{2}$$
wherein σ and μ are the mean value and the variance in normal distribution of the hidden layer variable output by the encoder, μ′ is an output result of the decoder, xᵢ is the second magnetic resonance weighted image with the corresponding contrast, i is an input sample, j is an input sample used to extract contrast encoding information, and n and d are the corresponding amount of samples input when the loss function is calculated once.

10. A variational autoencoder-based magnetic resonance weighted image synthesis device, comprising a memory and one or more processors, wherein the memory stores executable codes therein, and the one or more processors, when executing the executable codes, are configured to implement the variational autoencoder-based magnetic resonance weighted image synthesis method of claim 1.

11. A non-transitory computer-readable storage medium storing a program thereon, wherein the program, when executed by a processor, implements the variational autoencoder-based magnetic resonance weighted image synthesis method of claim 1.
